(19) United States
(12) Patent Application Publication
(10) Pub. No.: US 2014/0027770 A1
(43) Pub. Date: Jan. 30, 2014

(54) SEMICONDUCTOR LAMINATE AND PROCESS FOR PRODUCTION THEREOF, AND SEMICONDUCTOR ELEMENT

(71) Applicants: Kazuyuki Iizuka, Tokyo (JP); Yoshikatsu Morishima, Tokyo (JP); Shinkuro Sato, Tokyo (JP)

(72) Inventors: Kazuyuki Iizuka, Tokyo (JP); Yoshikatsu Morishima, Tokyo (JP); Shinkuro Sato, Tokyo (JP)

(21) Appl. No.: 14/110,420

(22) PCT Filed: Apr. 3, 2012
(86) PCT No.: PCT/JP2012/059096

§ 371 Date: Oct. 7, 2013

(30) Foreign Application Priority Data
Apr. 8, 2011 (JP) 2011-086806

(51) Int. Cl. H01L 29/267

(52) U.S. Cl. CPC H01L 29/267
USPC 257/43; 438/104

(57) ABSTRACT

A semiconductor laminate having small electric resistivity in the thickness direction; a process for producing the semiconductor laminate; and a semiconductor element equipped with the semiconductor laminate. include a semiconductor laminate including a Ga₂0₃ substrate; an AlGalnN buffer layer which is formed on the Ga₂0₃ substrate; a nitride semiconductor layer which is formed on the AlGalnN buffer layer and contains Si; and an Si-rich region which is formed in an area located on the AlGalnN buffer layer side in the nitride semiconductor layer and has an Si concentration of 5×10¹⁸/cm³ or more.

### TECHNICAL FIELD

The invention relates to a semiconductor laminate, a process of producing the semiconductor laminate and a semiconductor element.

### BACKGROUND ART

Conventionally, a semiconductor element including a semiconductor laminate composed of a Ga₂O₃ substrate, an AlN buffer layer and a GaN layer is known (see, e.g., PTL 1). According to Patent Literature 1, the AlN buffer layer is formed to have a thickness of 10 to 30 nm by growing an AlN crystal on the Ga₂O₃ substrate. In addition, the GaN layer, which is formed by growing a GaN crystal on the AlN buffer layer, contains Si as a donor.

### CITATION LIST

### Patent Literature

[PTL 1] JP-A-2006-310765

### SUMMARY OF INVENTION

### Technical Problem

In a vertical-type element with vertical current flow such as the semiconductor element of PTL 1, it is important to reduce electrical resistivity of the semiconductor laminate in a thickness direction.

Therefore, it is an object of the invention to provide a semiconductor laminate having small electrical resistivity in the thickness direction, a process of producing the semiconductor laminate, and a semiconductor element equipped with the semiconductor laminate.

### Solution to Problem

In order to achieve the above-mentioned object, the present invention provides a semiconductor laminate in [1] to [5], a semiconductor element in [6] and a process for producing the semiconductor laminate in [7] to [11].
[1] A semiconductor laminate comprises:

a Ga₂O₃ substrate;

a buffer layer that is formed on the Ga₂O₃ substrate and comprises an AlₓGa_{y}In_{z}N (0≦x≦1, 0≦y≦1, 0≦z≦1 and x+y+z=1) crystal; and

a nitride semiconductor layer that is formed on the buffer layer and comprises an AlₓGa_{y}In_{z}N (0≦x≦1, 0≦y≦1, 0≦z≦1 and x+y+z=1) crystal with Si doped therein,

wherein the nitride semiconductor layer comprises a high Si concentration region formed in a region on a side of the buffer layer and having a Si concentration of not less than 5×10¹⁸/cm³.
[2] The semiconductor laminate according to [1], wherein the high Si concentration region has a thickness of not less than 2 nm.
[3] The semiconductor laminate according to [1] or [2], wherein the buffer layer has a thickness of not less than 0.5 nm and not more than 10 nm.
[4] The semiconductor laminate according to [1], wherein the AlₓGa_{y}In_{z}N crystal of the buffer layer comprises an AlN crystal.
[5] The semiconductor laminate according to [1], wherein the AlₓGa_{y}In_{z}N crystal of the nitride semiconductor layer comprises a GaN crystal.
[6] A semiconductor element comprises a semiconductor laminate comprising:

a Ga₂O₃ substrate;

a buffer layer that is formed on the Ga₂O₃ substrate and comprises an AlₓGa_{y}In_{z}N (0≦x≦1, 0≦y≦1, 0≦z≦1 and x+y+z=1) crystal; and

a nitride semiconductor layer that is formed on the buffer layer and comprises an AlₓGa_{y}In_{z}N (0≦x≦1, 0≦y≦1, 0≦z≦1 and x+y+z=1) crystal with Si doped therein,

wherein the nitride semiconductor layer comprises a high Si concentration region formed in a region on a side of the buffer layer and having a Si concentration of not less than 5×10¹⁸/cm³, and

wherein an electric current is fed in a direction of a thickness of the semiconductor laminate.
[7] A process of producing a semiconductor laminate comprises: a step of forming a buffer layer by epitaxially growing an AlₓGa_{y}In_{z}N (0≦x≦1, 0≦y≦1, 0≦z≦1 and x+y+z=1) crystal on a Ga₂O₃ substrate; and

a step of forming a nitride semiconductor layer by growing an AlₓGa_{y}In_{z}N (0≦x≦1, 0≦y≦1, 0≦z≦1 and x+y+z=1) crystal on the buffer layer while adding Si,

wherein a high Si concentration region having a Si concentration of not less than 5×10¹⁸/cm³ is formed in the nitride semiconductor layer by increasing a doping concentration of Si at an initial stage in growing the AlₓGa_{y}In_{z}N crystal.
[8] The process of producing a semiconductor laminate according to [7], wherein the high Si concentration region is adapted to have a thickness of not less than 2 nm.
[9] The process of producing a semiconductor laminate according to [7] or [8], wherein the buffer layer is adapted to have a thickness of not less than 0.5 nm and not more than 10 nm.
[10] The process of producing a semiconductor laminate according to [7], wherein the AlₓGa_{y}In_{z}N crystal of the buffer layer comprises an AlN crystal.
[11] The process of producing a semiconductor laminate according to [7], wherein the AlₓGa_{y}In_{z}N crystal of the nitride semiconductor layer comprises a GaN crystal.

### Advantageous Effects of Invention

According to the invention, it is possible to provide a semiconductor laminate having small electrical resistivity in the thickness direction, a process of producing the semiconductor laminate, and a semiconductor element equipped with the semiconductor laminate.

### BRIEF DESCRIPTION OF DRAWINGS

FIG. 1 is a cross sectional view showing a semiconductor laminate in a first embodiment.

FIG. 2 is a cross sectional view showing a vertical FET in a second embodiment.

FIG. 3 is a cross sectional view showing a vertical FET in a third embodiment.

FIG. 4 is a cross sectional view showing a vertical FET in a fourth embodiment.

FIG. 5 is a cross sectional view showing a vertical FET in a fifth embodiment.

FIG. 6 is a cross sectional view showing a HBT in a sixth embodiment.

FIG. 7 is a cross sectional view showing a SBD in a seventh embodiment.

FIG. 8 is a cross sectional view showing an LED in an eighth embodiment.

FIG. 9 is a graph showing a relation between a Si concentration of a high Si concentration region and voltage drop in Example 1.

FIG. 10 is a graph showing a relation between a thickness of an AlGaInN buffer layer and voltage drop in Example 2.

FIG. 11 is a graph showing a relation between a thickness of the high Si concentration region and voltage drop in Example 3.

### DESCRIPTION OF EMBODIMENTS

In the present embodiments, it is possible to form a semiconductor laminate which is composed of a Ga₂O₃ substrate, an AlGaInN buffer layer formed of an AlₓGa_{y}In_{z}N (0≦x≦1, 0≦y≦1, 0≦z≦1 and x+y+z=1) crystal and a nitride semiconductor layer formed of an AlₓGa_{y}In_{z}N (0≦x≦1, 0≦y≦1, 0≦z≦1 and x+y+z=1) crystal and has small electrical resistivity in a thickness direction. The inventors found that electrical resistivity of the semiconductor laminate in the thickness direction is reduced by increasing a concentration of Si as a donor in the nitride semiconductor layer in the vicinity of a surface on the AlGaInN buffer layer side. Furthermore, it was found that it is possible to further reduce the electrical resistivity of the semiconductor laminate in the thickness direction by forming the AlGaInN buffer layer so as to have a specific thickness.

Among AlₓGa_{y}In_{z}N crystals, an AlN crystal (x=1, y=z=0) is particularly preferable to form the AlGaInN buffer layer. In this case, adhesion between the Ga₂O₃ substrate and the nitride semiconductor layer is further increased.

Meanwhile, among AlₓGa_{y}In_{z}N crystals, a GaN crystal (y=1, x=z=0) with good crystal quality is particularly preferable to form the nitride semiconductor layer.

In addition, in the present embodiments, use of a semiconductor laminate having small electrical resistivity in the thickness direction allows a high-performance semiconductor element to be formed. Examples of the embodiments will be described in detail below.

### First Embodiment

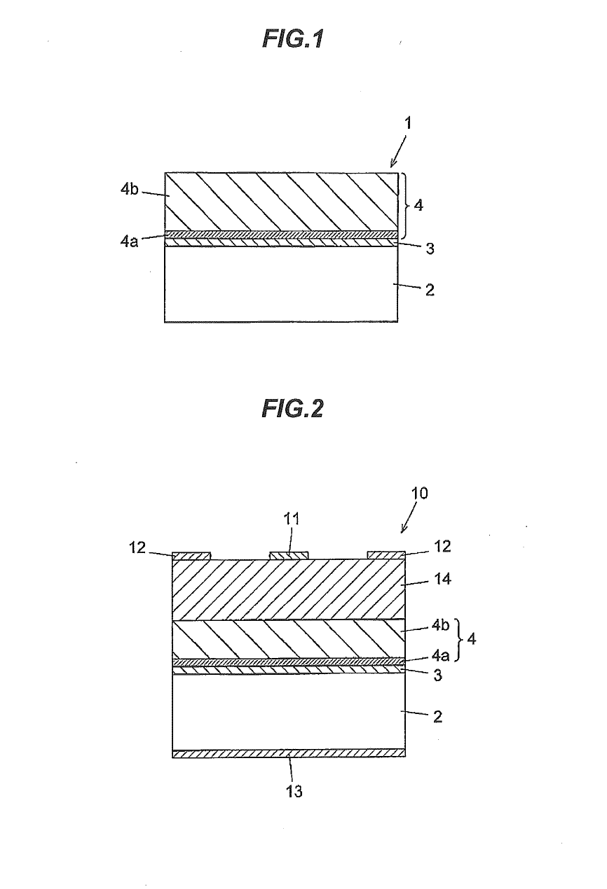

FIG. 1 is a cross sectional view showing a semiconductor laminate 1 in the first embodiment. The semiconductor laminate 1 includes a Ga₂O₃ substrate 2, an AlGaInN buffer layer 3 and a nitride semiconductor layer 4.

The Ga₂O₃ substrate 2 is formed of a β-Ga₂O₃ single crystal. The Ga₂O₃ substrate 2 is preferably a substrate of which principal surface is a plane with oxygen in a hexagonal grid arrangement, i.e., any of (101), (−201), (301) and (3-10) planes. In this case, even if the AlGaInN buffer layer 3 is thin (e.g., not more than 10 nm), an AlₓGa_{y}In_{z}N (0≦x≦1, 0≦y≦1, 0≦z≦1 and x+y+z=1) crystal having a flat surface can be grown on the AlGaInN buffer layer 3 to form the nitride semiconductor layer 4. It is particularly preferable that the principal surface of the Ga₂O₃ substrate 2 be a (101) plane.

An AlₓGa_{y}In_{z}N (0≦x≦1, 0≦y≦1, 0≦z≦1 and x+y+z=1) crystal is epitaxially grown on the Ga₂O₃ substrate 2 by a MOCVD (Metal Organic Chemical Vapor Deposition) method, etc., thereby forming the AlGaInN buffer layer 3. A growth temperature of the AlₓGa_{y}In_{z}N crystal is 350 to 600° C., particularly preferably 380 to 500° C.

Among AlₓGa_{y}In_{z}N crystals, an AlN crystal (x=1, y=z=0) is particularly preferable to form the AlGaInN buffer layer 3. When the AlGaInN buffer layer 3 is formed of the AlN crystal, adhesion between the Ga₂O₃ substrate 2 and the nitride semiconductor layer 4 is further increased.

The thickness of the AlGaInN buffer layer 3 is 0.5 to 10 nm In this case, it is possible to greatly reduce electrical resistivity of the semiconductor laminate 1 in the thickness direction.

An AlₓGa_{y}In_{z}N (0≦x≦1, 0≦y≦1, 0≦z≦1 and x+y+z=1) crystal is epitaxially grown on the AlGaInN buffer layer 3 by the MOCVD method, etc., while adding Si, thereby forming the nitride semiconductor layer 4. A growth temperature of the AlₓGa_{y}In_{z}N crystal is, e.g., 800 to 1100° C. The thickness of the nitride semiconductor layer 4 is, e.g., 2 μm. Among AlₓGa_{y}In_{z}N crystals, a GaN crystal (y=1, x=z=0) with good crystal quality is particularly preferable to form the nitride semiconductor layer 4.

The nitride semiconductor layer 4 contains Si as a donor. The nitride semiconductor layer 4 includes a high Si concentration (or Si-rich) region 4a in the vicinity of a surface on the AlGaInN buffer layer 3 side. The high Si concentration region 4a is formed by adding a higher amount of Si at the initial stage of the growth of the AlₓGa_{y}In_{z}N crystal on the AlGaInN buffer layer 3.

The Si concentration of the high Si concentration region 4a is higher than that of remaining region 4b. The Si concentration of the high Si concentration region 4a is not less than 5×10¹⁸/cm³, particularly preferably not less than 1×10¹⁹/cm³.

The thickness of the high Si concentration region 4a is preferably not less than 2 nm.

### Second Embodiment

A vertical FET (field effect transistor) including the semiconductor laminate 1 of the first embodiment will be described as the second embodiment.

FIG. 2 is a cross sectional view showing a vertical FET 10 which is a semiconductor element according to the second embodiment. The vertical FET 10 includes the semiconductor laminate 1 in which the Ga₂O₃ substrate 2, the AlGaInN buffer layer 3 and the nitride semiconductor layer 4 are included, a GaN-based vertical FET 14 formed on a surface (upper surface in FIG. 2) of the nitride semiconductor layer 4, a gate electrode 11 and a source electrode 12 which are formed on the GaN-based vertical FET 14, and a drain electrode 13 formed on a surface (lower surface in FIG. 2) of the Ga₂O₃ substrate 2.

It should be noted that the vertical FET 10 is an example of a vertical FET which can be formed using the semiconductor laminate 1.

### Third Embodiment

A vertical FET including the semiconductor laminate 1 of the first embodiment and having a MIS (metal insulator semiconductor) gate structure will be described as the third embodiment.

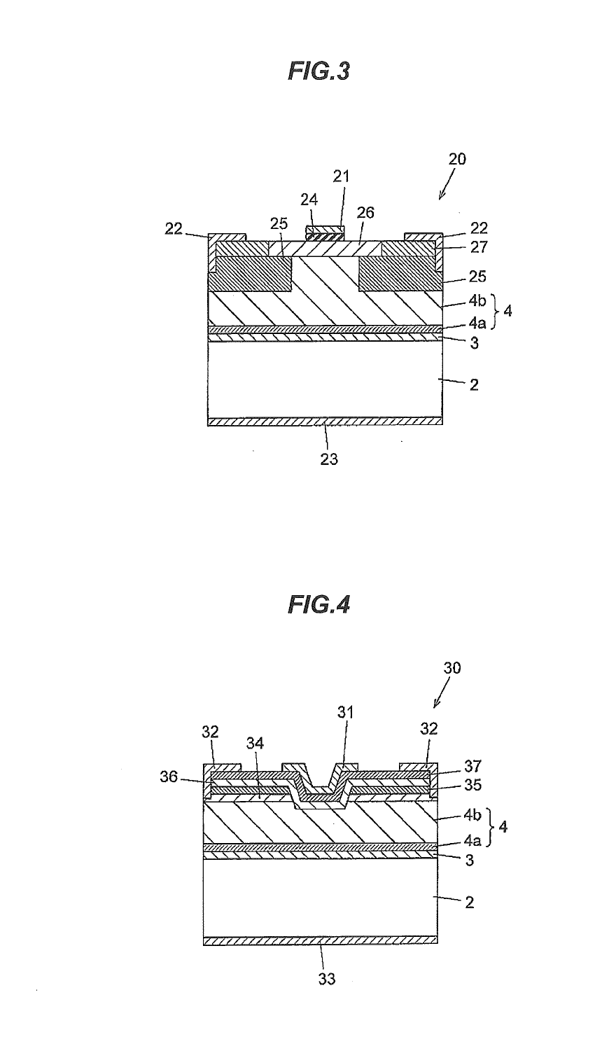

FIG. 3 is a cross sectional view showing a vertical FET 20 which is a semiconductor element according to the third embodiment. The vertical FET 20 includes the semiconductor laminate 1 in which the Ga₂O₃ substrate 2, the AlGaInN buffer layer 3 and the nitride semiconductor layer 4 are included, a P⁺ region 25 formed by introducing a p-type impurity into the region 4b, an Al_{0.2}Ga_{0.8}N layer 26 formed on a surface (upper surface in FIG. 3) of the nitride semiconductor layer 4, an n⁺ region 27 formed by introducing an n-type impurity such as Si into the Al_{0.2}Ga_{0.8}N layer 26, a gate electrode 21 formed on the Al_{0.2}Ga_{0.8}N layer 26 via a gate insulator film 24, a source electrode 22 connected to the n⁺ region 27 as well as to the p⁺ region 25, and a drain electrode 23 formed on a surface (lower surface in FIG. 3) of the Ga₂O₃ substrate 2.

Here, the region 4b has, e.g., a thickness of 6 μm and a Si concentration of 1×10¹⁸/cm³. Meanwhile, the P⁺ region 25 has, e.g., a thickness of 1 μm and a p-type impurity concentration of 1×10¹⁸/cm³. The Al_{0.2}Ga_{0.8}N layer 26 does not contain impurities. The source electrode 22 and the drain electrode 23 are laminates of, e.g., Ti film and Al film. The gate electrode 21 and the gate insulator film 24 are respectively formed of, e.g., Al and SiO₂.

It should be noted that the vertical FET 20 is an example of a vertical FET having a MIS gate structure which can be formed using the semiconductor laminate 1.

### Fourth Embodiment

A vertical FET including the semiconductor laminate 1 of the first embodiment and having a Schottky gate structure will be described as the fourth embodiment.

FIG. 4 is a cross sectional view showing a vertical FET 30 which is a semiconductor element according to the fourth embodiment. The vertical FET 30 includes the semiconductor laminate 1 in which the Ga₂O₃ substrate 2, the AlGaInN buffer layer 3 and the nitride semiconductor layer 4 are included, a P⁺-GaN layer 34, an n⁺-GaN layer 35, a GaN layer 36 and an Al_{0.2}Ga_{0.8}N layer 37 which are sequentially laminated on a surface (upper surface in FIG. 4) of the nitride semiconductor layer 4, a gate electrode 31 formed on the Al_{0.2}Ga_{0.8}N layer 37, a source electrode 32 connected to the P⁺-GaN layer 34, to the n⁺-GaN layer 35, to the GaN layer 36 and to the Al_{0.2}Ga_{0.8}N layer 37, and a drain electrode 33 formed on a surface (lower surface in FIG. 4) of the Ga₂O₃ substrate 2.

Here, the region 4b has, e.g., a thickness of 6 μm and a Si concentration of 1×10¹⁶/cm³. Meanwhile, the P⁺-GaN layer 34 has, e.g., a thickness of 1 μm and a p-type impurity concentration of 1×10¹⁸/cm³. In addition, the n⁺-GaN layer 35 has, e.g., a thickness of 200 nm and an n-type impurity concentration of 1×10¹⁸/cm³. The GaN layer 36 does not contain impurities and has a thickness of, e.g., 100 nm. The Al_{0.2}Ga_{0.8}N layer 37 does not contain impurities and has a thickness of, e.g., 30 nm. The source electrode 32 and the drain electrode 33 are laminates of, e.g., Ti film and Al film. The gate electrode 31 is a laminate of, e.g., Ni film and Au film.

It should be noted that the vertical FET 30 is an example of a vertical FET having a Schottky gate structure which can be formed using the semiconductor laminate 1.

### Fifth Embodiment

Another vertical FET including the semiconductor laminate 1 of the first embodiment and having a Schottky gate structure will be described as the fifth embodiment.

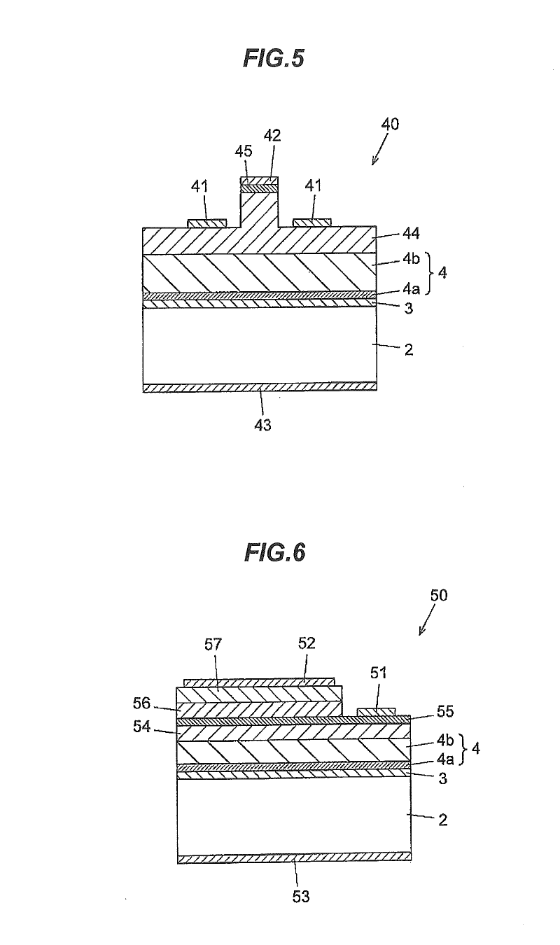

FIG. 5 is a cross sectional view showing a vertical FET 40 which is a semiconductor element according to the fifth embodiment. The vertical FET 40 includes the semiconductor laminate 1 in which the Ga₂O₃ substrate 2, the AlGaInN buffer layer 3 and the nitride semiconductor layer 4 are included, an n⁻-GaN layer 44 formed on a surface (upper surface in FIG. 5) of the nitride semiconductor layer 4, a gate electrode 41 formed on a flat portion of the n⁻-GaN layer 44, a source electrode 42 formed on a raised of the n⁻-GaN layer 44 via an n⁺-InAlGaN contact layer 45, and a drain electrode 43 formed on a surface (lower surface in FIG. 5) of the Ga₂O₃ substrate 2.

Here, the region 4b has, e.g., a thickness of 6 μm and a Si concentration of 1×10¹⁸/cm³. Meanwhile, the flat portion of the n⁻-GaN layer 44 has, e.g., a thickness of 3 μm and an n-type impurity concentration of 1×10¹⁶/cm³. The source electrode 42 is formed of, e.g., WSi. The drain electrode 43 is a laminate of, e.g., Ti film and Al film. The gate electrode 41 is formed of, e.g., PdSi.

It should be noted that the vertical FET 40 is an example of a vertical FET having a Schottky gate structure which can be formed using the semiconductor laminate 1.

### Sixth Embodiment

A heterojunction bipolar transistor (HBT) including the semiconductor laminate 1 of the first embodiment will be described as the sixth embodiment.

FIG. 6 is a cross sectional view showing a HBT 50 which is a semiconductor element according to the sixth embodiment. The HBT 50 includes the semiconductor laminate 1 in which the Ga₂O₃ substrate 2, the AlGaInN buffer layer 3 and the nitride semiconductor layer 4 are included, an n⁻-GaN layer 54 and a P⁺-GaN layer 55 which are laminated on a surface (upper surface in FIG. 6) of the nitride semiconductor layer 4, an n⁺-Al_{0.1}Ga_{0.9}N layer 56 and an n⁺-GaN layer 57 which are laminated on the P⁺-GaN layer 55, a base electrode 51 formed on the P⁺-GaN layer 55, an emitter electrode 52 formed on the n⁺-GaN layer 57, and a collector electrode 53 formed on a surface (lower surface in FIG. 6) of the Ga₂O₃ substrate 2.

Here, the region 4b has, e.g., a thickness of 4 μm and a Si concentration of 1×10¹⁸/cm³. Meanwhile, the n⁻-GaN layer 54 has, e.g., a thickness of 2 μm and an n-type impurity concentration of 1×10¹⁶/cm³. In addition, the P⁺-GaN layer 55 has, e.g., a thickness of 100 nm and a p-type impurity concentration of 1×10¹⁸/cm³. Then, the n⁺-Al_{0.1}Ga_{0.9}N layer 56 has, e.g., a thickness of 500 nm and an n-type impurity concentration of 1×10¹⁸/cm³. In addition, the n⁺-GaN layer 57 has, e.g., a thickness of 1 μm and an n-type impurity concentration of 1×10¹⁸/cm³. The emitter electrode 52 is a laminate of, e.g., Ti film and Al film. The collector electrode 53 is a laminate of, e.g., Ti film and Au film. The base electrode 51 is a laminate of, e.g., Ni film and Au film.

It should be noted that the HBT 50 is an example of a heterojunction bipolar transistor which can be formed using the semiconductor laminate 1.

### Seventh Embodiment

A Schottky-barrier diode (SBD) including the semiconductor laminate 1 of the first embodiment will be described as the seventh embodiment.

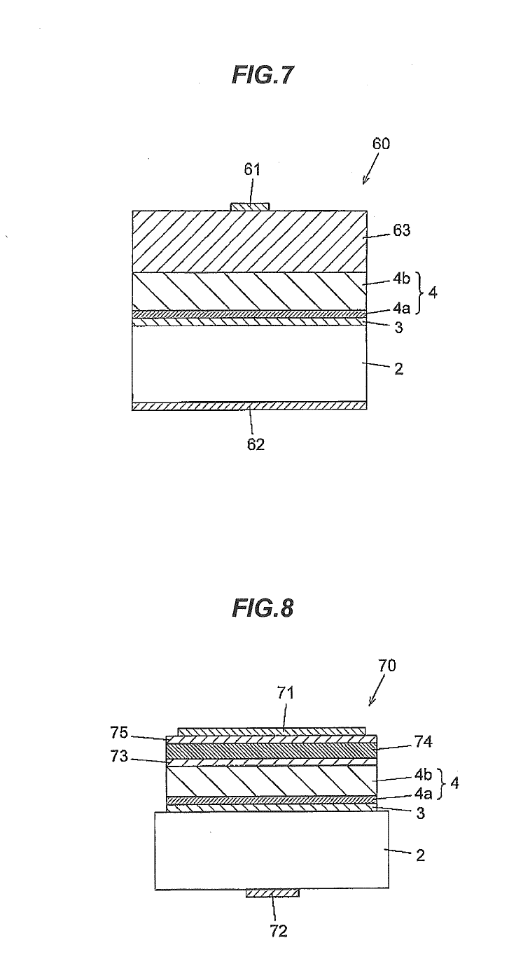

FIG. 7 is a cross sectional view showing a SBD 60 which is a semiconductor element according to the seventh embodiment. The SBD 60 includes the semiconductor laminate 1 in which the Ga₂O₃ substrate 2, the AlGaInN buffer layer 3 and the nitride semiconductor layer 4 are included, an n⁻-GaN layer 63 formed on a surface (upper surface in FIG. 7) of the nitride semiconductor layer 4, an anode electrode 61 formed on the n⁻-GaN layer 63, and a cathode electrode 62 formed on a surface (lower surface in FIG. 7) of the Ga₂O₃ substrate 2.

Here, the region 4b has, e.g., a thickness of 6 μm and a Si concentration of 1×10¹⁸/cm³. Meanwhile, the n⁻-GaN layer 63 has, e.g., a thickness of 7 μm and an n-type impurity concentration of 1×10¹⁶/cm³. The anode electrode 61 is formed of, e.g., Au. The cathode electrode 62 is a laminate of, e.g., Ti film and Al film.

it should be noted that, the SBD 60 is an example of a Schottky-barrier diode which can be formed using the semiconductor laminate 1.

### Eighth Embodiment

A light-emitting diode (LED) including the semiconductor laminate 1 of the first embodiment will be described as the eighth embodiment.

FIG. 8 is a cross sectional view showing an LED 70 which is a semiconductor element according to the eighth embodiment. The LED 70 includes the semiconductor laminate 1 in which the Ga₂O₃ substrate 2, the AlGaInN buffer layer 3 and the nitride semiconductor layer 4 are included, an emission layer 73, a p-type cladding layer 74 and a p-type contact layer 75 which are laminated on a surface (upper surface in FIG. 8) of the nitride semiconductor layer 4, a p-electrode 71 formed on the p-type contact layer 75, and an n-electrode 72 formed on a surface (lower surface in FIG. 8) of the Ga₂O₃ substrate 2.

Here, the region 4b has, e.g., a thickness of 5 μm and a Si concentration of 1×10¹⁸/cm³. The region 4b functions as an n-type cladding layer. Meanwhile, the emission layer 73 includes, e.g., three pairs of multiple quantum well structures each composed of an 8 nm-thick GaN crystal and a 2 nm-thick InGaN crystal. Then, the p-type cladding layer 74 is, e.g., formed of a GaN crystal with a Si concentration of 5.0×10¹⁹/cm³ and has a thickness of 150 nm. In addition, the p-type contact layer 75 is, e.g., formed of a GaN crystal with a Mg concentration of 1.5×10²⁰/cm³ and has a thickness of 10 nm.

It should be noted that the LED 70 is an example of a light-emitting diode which can be formed using the semiconductor laminate 1.

### Effects of Embodiments

In the first embodiment, the high Si concentration region 4a having a Si concentration of not less than 5×10¹⁸/cm³ is formed in the nitride semiconductor layer 4 and it is thereby possible to form the semiconductor laminate 1 having small electrical resistivity in the thickness direction. It is considered that this is because electrons tunnel through potential barrier at a hetero-interface by forming the high Si concentration region 4a having a high Si concentration and this allows an electric current to pass through easily.

In addition, the high Si concentration region 4a with a thickness of not less than 2 nm allows the electric resistivity of the semiconductor laminate in the thickness direction to be further reduced. Furthermore, the AlGaInN buffer layer with a thickness of not less than 0.5 nm and not more than 10 nm allows the electric resistivity of the semiconductor laminate in the thickness direction to be further reduced.

In addition, according to the second to eighth embodiments, it is possible to obtain a high-performance vertical by forming a vertical semiconductor element which includes the semiconductor laminate 1 and in which a current passes in a thickness direction of the semiconductor laminate 1.

The semiconductor laminate 1 in the present embodiments was evaluated as shown in the following Examples 1 to 4.

### EXAMPLE 1

In Example 1, plural semiconductor laminates 1 having high Si concentration regions 4a with different impurity concentrations were formed to examine a relation between an impurity concentration of the high Si concentration region 4a and electrical resistivity of the semiconductor laminate 1 in the thickness direction. Each semiconductor laminate 1 was formed by the following process.

Firstly, the Ga₂O₃ substrate 2 was placed in a MOCVD apparatus and an AlN crystal was grown on the Ga₂O₃ substrate 2 at a growth temperature of 450° C., thereby forming the AlGaInN buffer layer 3 having a thickness of 5 nm.

Subsequently, a GaN crystal was grown on the AlGaInN buffer layer 3 at a growth temperature of 1050° C. while adding Si, thereby forming the nitride semiconductor layer 4 having a thickness of 2 μm. At this time, the high Si concentration region 4a having a thickness of 10 nm was formed by adding a higher amount of Si at the initial stage of the GaN crystal growth. The impurity concentration of the region 4b was 2×10¹⁸/cm³.

Next, electrodes were formed respectively on surfaces of the Ga₂O₃ substrate 2 and the nitride semiconductor layer 4 by photolithography and deposition techniques. Then, voltage was applied between the electrodes and voltage drop at a current density of 200 A/cm² was measured.

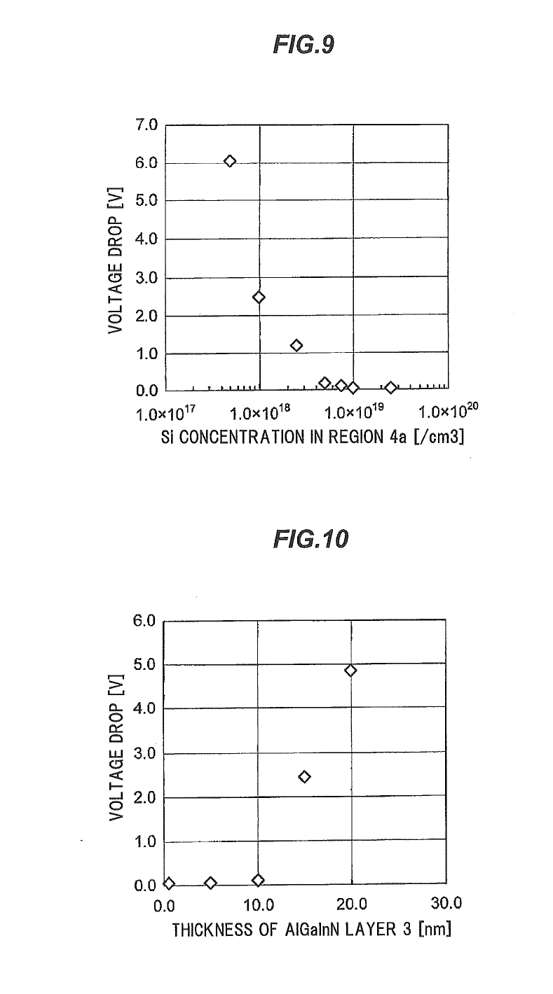

FIG. 9 is a graph showing a relation between a Si concentration of the high Si concentration region 4a and voltage drop at a current density of 200 A/cm². As shown FIG. 9, the higher the Si concentration of the high Si concentration region 4a, the smaller the voltage drop, i.e., the lower the electrical resistivity of the semiconductor laminate 1 in the thickness direction.

It is understood that the electrical resistivity of the semiconductor laminate 1 in the thickness direction is low, especially when the Si concentration of the high Si concentration region 4a is not less than 5×10¹⁸/cm³. It is also understood that the voltage drop value is substantially constant when the Si concentration of the high Si concentration region 4a is not less than 1×10¹⁹/cm³.

### EXAMPLE 2

In Example 2, plural semiconductor laminates 1 having AlGaInN buffer layers 3 with different thicknesses in a range of 0.5 to 20 nm were formed to examine a relation between a thickness of the AlGaInN buffer layer 3 and the electrical resistivity of the semiconductor laminate 1 in the thickness direction. Each semiconductor laminate 1 was formed by the following process.

Firstly, the Ga₂O₃ substrate 2 was placed in a MOCVD apparatus and an AlN crystal was grown on the Ga₂O₃ substrate 2 at a growth temperature of 450° C., thereby forming the AlGaInN buffer layer 3.

Subsequently, a GaN crystal was grown on the AlGaInN buffer layer 3 at a growth temperature of 1050° C. while adding Si, thereby forming the nitride semiconductor layer 4 having a thickness of 2 μm. At this time, the high Si concentration region 4a having a thickness of 10 nm was formed by adding a higher amount of Si at the initial stage of the GaN crystal growth. The Si concentration of the high Si concentration region 4a and that of the region 4b were respectively 2×10¹⁹/cm³ and 2×10¹⁸/cm³.

Next, electrodes were formed respectively on surfaces of the Ga₂O₃ substrate 2 and the nitride semiconductor layer 4 by photolithography and deposition techniques. Then, voltage was applied between the electrodes and voltage drop at a current density of 200 A/cm² was measured.

FIG. 10 is a graph showing a relation between a thickness of the AlGaInN buffer layer 3 and voltage drop at a current density of 200 A/cm². As shown FIG. 10, the smaller the thickness of the AlGaInN buffer layer 3, the smaller the voltage drop, i.e., the lower the electrical resistivity of the semiconductor laminate 1 in the thickness direction.

It is understood that the electrical resistivity of the semiconductor laminate 1 in the thickness direction is low, especially when the thickness of the AlGaInN buffer layer 3 is not more than 10 nm. In addition, it is understood that when the AlGaInN buffer layer 3 is thick, the electrical resistivity of the semiconductor laminate 1 in the thickness direction is high even if the Si concentration of the high Si concentration region 4a is enough high (2×10¹⁹/cm³).

### EXAMPLE 3

In Example 3, plural semiconductor laminates 1 having high Si concentration regions 4a with different thicknesses in a range of 0 to 10 nm were formed to examine a relation between a thickness of the high Si concentration region 4a and the electrical resistivity of the semiconductor laminate 1 in the thickness direction. Each semiconductor laminate 1 was formed by the following process.

Firstly, the Ga₂O₃ substrate 2 was placed in a MOCVD apparatus and an AlN crystal was grown on the Ga₂O₃ substrate 2 at a growth temperature of 450° C., thereby forming the AlGaInN buffer layer 3 having a thickness of 5 nm.

Subsequently, a GaN crystal was grown on the AlGaInN buffer layer 3 at a growth temperature of 1050° C. while adding Si, thereby forming the nitride semiconductor layer 4 having a thickness of 2 μm. At this time, the high Si concentration region 4a was formed by adding a higher amount of Si at the initial stage of the GaN crystal growth. The Si concentration of the high Si concentration region 4a and that of the region 4b were respectively 2×10¹⁹/cm³ and 2×10¹⁸/cm³.

Next, electrodes were formed respectively on surfaces of the Ga₂O₃ substrate 2 and the nitride semiconductor layer 4 by photolithography and deposition techniques. Then, voltage was applied between the electrodes and voltage drop at a current density of 200 A/cm² was measured.

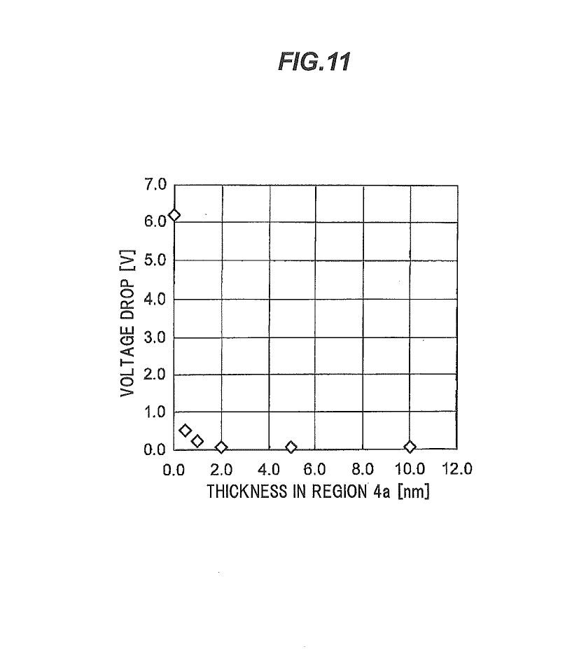

FIG. 11 is a graph showing a relation between the thickness of the high Si concentration region 4a and voltage drop at a current density of 200 A/cm². As shown FIG. 11, the greater the thickness of the high Si concentration region 4a, the smaller the voltage drop, i.e., the lower the electrical resistivity of the semiconductor laminate 1 in the thickness direction.

It is understood that the electrical resistivity of the semiconductor laminate 1 in the thickness direction is low, especially when the thickness of the high Si concentration region 4a is not less than 2 nm.

### EXAMPLE 4

In Example 4, the LED 70 in the eighth embodiment was formed and forward voltage drop V_{F} was measure.

Firstly, a Si-doped n-type β-Ga₂O₃ substrate was prepared as the Ga₂O₃ substrate 2. Here, the β-Ga₂O₃ substrate has a thickness of 400 μm and a principal surface of (101) plane.

Next, 5 nm of AlN crystal was grown on the β-Ga₂O₃ substrate using a MOCVD apparatus at a growth temperature of 450° C., thereby forming the AlGaInN buffer layer 3. Next, the high Si concentration region 4a was formed by growing 10 nm of GaN crystal having a Si concentration of 2.0×10¹⁹/cm³ at a growth temperature of 1050° C. and the region 4b as an n-type cladding layer was subsequently formed by growing 5 μm of GaN crystal having a Si concentration of 1.0×10¹⁸/cm³.

Next, three pairs of multiple quantum well structures each composed of an 8 nm-thick GaN crystal and a 2 nm-thick InGaN crystal were formed at a growth temperature of 750° C. and 10 μm of GaN crystal was further grown, thereby forming the emission layer 73.

Next, 150 nm of GaN crystal having a Mg concentration of 5.0×10¹⁹/cm³ was grown at a growth temperature of 1000° C., thereby forming the p-type cladding layer 74. Next, 10 nm of GaN crystal having a Mg concentration of 1.5×10²⁰/cm³ was grown at a growth temperature of 1000° C., thereby forming the p-type contact layer 75.

In the above process, TM (trimethylgallium) was used as a Ga source, TMI (trimethylindium) as an In source, SiH₃CH₃ (monomethylsilane) gas as a Si source, Cp₂Mg (cyclopentadienylmagnesium) as a Mg source and NH₃ (ammonia) gas as an N source.

A surface of the LED epitaxial wafer obtained as described above was etched from the p-type contact layer 75 side to a position deeper than the emission layer 73 using an ICP-RIE system to shape into a mesa shape. Next, a SiO₂ film was formed on a side surface of the emission layer 73 using a sputtering apparatus. On the p-type contact layer 75 and the Ga₂O₃ substrate 2, electrodes respectively in ohmic-contact therewith were further formed using a deposition apparatus, thereby obtaining the LED 70 in which a light extraction surface is located on the Ga₂O₃ substrate 2 side.

Meanwhile, an LED which has a 20 nm-thick AlGaInN buffer layer 3 and does not include the high Si concentration region 4a was formed as Comparative Example.

After that, the LED 70 and the LED of Comparative Example were respectively mounted on a can-type stem using Ag paste, and the voltage drop V_{F} at a current I_{F} of 20 mA was measured. As a result, the voltage drop V_{F} of the LED 70 was 2.94V while that of the conventional LED in Comparative Example was 4.32V, and it was confirmed that the voltage drop V_{F} of the LED 70 is at a level allowing its practical use as a light-emitting element.

Although the embodiments and examples of the invention have been described above, the invention according to claims is not to be limited to the above-described embodiments and examples. Further, it should be noted that all combinations of the features described in the embodiments and examples are not necessary to solve the problem of the invention.

### REFERENCE SIGNS LIST

1 Semiconductor laminate
2 Ga₂O₃ substrate
3 AlGaInN buffer layer
4 Nitride semiconductor layer
4a High Si concentration region
4b Region
10, 20, 30, 40 Vertical FET
50 HBT
60 SBT
70 LED

1. A semiconductor laminate, comprising:
a Ga₂0₃ substrate;
a buffer layer that is formed on the Ga₂0₃ substrate and comprises an AlₓGa_{y}In_{z}N (O≦x≦1, O≦y≦1, O≦z≦1 and x+y+z=1) crystal; and
a nitride semiconductor layer that is formed on the buffer layer and comprises an AlₓGa_{y}In_{z}N (O≦x≦1, O≦y≦1, O≦z≦1 and x+y+z=1) crystal with Si doped therein,
wherein the nitride semiconductor layer comprises a high Si concentration region formed in a region on a side of the buffer layer and having a Si concentration of not less than 5×10¹⁸/cm³.

2. The semiconductor laminate according to claim 1, wherein the high Si concentration region has a thickness of not less than 2 nm.

3. The semiconductor laminate according to claim 1, wherein the buffer layer has a thickness of not less than 0.5 nm and not more than 10 nm.

4. The semiconductor laminate according to claim 1, wherein the AlₓGa_{y}In_{z}N crystal of the buffer layer comprises an AIN crystal.

5. The semiconductor laminate according to claim 1, wherein the AlₓGa_{y}In_{z}N crystal of the nitride semiconductor layer comprises a GaN crystal.

6. A semiconductor element, comprising a semiconductor laminate comprising:
a Ga₂0₃ substrate;
a buffer layer that is formed on the Ga₂0₃ substrate and comprises an AlₓGa_{y}In_{z}N (O≦x≦1, O≦y≦1, O≦z≦1 and x+y+z=1) crystal; and
a nitride semiconductor layer that is formed on the buffer layer and comprises an AlₓGa_{y}In_{z}N (O≦x≦1, O≦y≦1, O≦z≦1 and x+y+z=1) crystal with Si doped therein,
wherein the nitride semiconductor layer comprises a high Si concentration region formed in a region on a side of the buffer layer and having a Si concentration of not less than 5×10¹⁸/cm³, and
wherein an electric current is fed in a direction of a thickness of the semiconductor laminate.

7. A process of producing a semiconductor laminate, comprising:
forming a buffer layer by epitaxially growing an AlₓGa_{y}In_{z}N (O≦x≦1, O≦y≦1, O≦z≦1 and x+y+z=1) crystal on a Ga₂0₃ substrate; and
forming a nitride semiconductor layer by growing an AlₓGa_{y}In_{z}N (O≦x≦1, O≦y≦1, O≦z≦1 and x+y+z=1) crystal on the buffer layer while adding Si,
wherein a high Si concentration region having a Si concentration of not less than 5×10¹⁸/cm³ is formed in the nitride semiconductor layer by increasing a doping concentration of Si at an initial stage in growing the AlₓGa_{y}In_{z}N crystal.

8. The process of producing a semiconductor laminate according to claim 7, wherein the high Si concentration region is adapted to have a thickness of not less than 2 nm.

9. The process of producing a semiconductor laminate according to claim 7, wherein the buffer layer is adapted to have a thickness of not less than 0.5 nm and not more than 10 nm.

10. The process of producing a semiconductor laminate according to claim 7, wherein the AlₓGa_{y}In_{z}N crystal of the buffer layer comprises an AIN crystal.

11. The process of producing a semiconductor laminate according to claim 7, wherein the AlₓGa_{y}In_{z}N crystal of the nitride semiconductor layer comprises a GaN crystal.
